(19) United States
(12) Patent Application Publication
(10) Pub. No.: US 2008/0297167 A1
(43) Pub. Date: Dec. 4, 2008

(54) Functional parametric tester and emulator of electronic modules and PCB's

(76) Inventor: Gilberto Antonio Possa, Campinas - SP (BR)

Correspondence Address: TRASK BRITT, P.O. BOX 2550, SALT LAKE CITY, UT, 84110, US

(21) Appl. No.: 12/148,939

(22) Filed: Apr. 22, 2008

(30) Foreign Application Priority Data
Apr. 23, 2007 (BR) PI 0705067-4

(51) Int. Cl. G01R 31/28

(52) U.S. Cl. 324/537

(57) ABSTRACT

New electro-electronic equipment Functional Parametric Tester and Emulator of Electronic Modules and PCB's. The Functional Parametric Tester and Emulator of Electronic Modules and PCB's is an equipment that allows performance of functional and parametric testing in a great variety of electronic circuits, electronic modules or electronic systems. The equipment's main characteristic is the programming ease and flexibility due to the embedded software with Electronic Circuit Library, which is a set of electronic circuits that allows the emulation of a great variety of electronic systems and execution of various functional automated tests.

### PRIORITY CLAIM

This application claims the benefit of the filing date of Brazilian Patent Application Serial No. PI 0705067-4, filed Apr. 23, 2007, for “FUNCTIONAL PARAMETRIC TESTER AND EMULATOR OF ELECTRONIC MODULES AND PCB'S.”

### TECHNICAL FIELD

The present report including illustrative drawings describes a new electro-electronic Functional Parametric Tester and Emulator equipment of Electronic Modules and electronic PCB's. The equipment allows performance of functional and parametric tests of a large variety of electronic circuits, modules or electronic systems. The most important features are the flexibility and easy programming.

The flexibility feature is provided by the Library of Electronic Circuits (BCE) that the equipment has. The BCE is a set of electronic circuits that allows emulation of a large variety of electronic systems, and thus enables the execution of various tests.

The ease of programming is given by the circuit denominated Micro-Test (uPT). The MicroTest is a circuit (hardware) with the ability to extend and execute complex commands, specializing in the execution of functional and parametric tests.

### BACKGROUND

The electronic industry sector, and particularly the industry of manufacturing and assembly of electronic printed circuits, modules and electronic equipments, has a large demand for parametric and functional testing solutions in the phase of final production tests, to assure the continued quality of the manufactured products.

Each company normally manufactures a plurality of product types, with variable quantities, with their own and various functional characteristics that require different functional and parametric test specifications.

Generally, the manufacturing industries do not get ready solutions in the market that allow quick and economical implementation and execute the required functional and parametric tests.

Therefore the industries have to adopt personalized solutions, designing equipment (Test Jig) dedicated to test one type of the manufactured PCB or electronic modules. The PCB or module to be tested is denominated the Unit Under Test (UST).

The problem with a personalized test system is that it has a fixed set of test functions dedicated to the type of UST for which it was designed, and becomes useless when the UST is modified or creates a new model, making it necessary to design and build a new equipment, which increases the economical cost and the time for the redesign of a new tester, besides making it necessary to have a stock of Test Jigs, one for each type of UST (Unit Under Test).

An alternative normally adopted by manufacturers of modules, equipment and electronic PCB with large volume in-series production for long time periods, such as cellular phones, television sets, personal computers, etc., is to search in the test market and purchase available and expensive large test equipment with a high complexity of programming, installation, operation, and high testing capacity, which is feasible only for the mass production of electro-electronic consumer products or large systems for the world market, such as, for example, telephone switching center office, routers, etc.

In order to reduce the cost of functional and parametric testing, creation of flexible equipment that, with the same hardware, could test various types of UST, changing only the software. In this way, it would not be necessary to spend time and money to design and assemble new equipment for each type of UST (Unit Under Test).

Another important factor is that programming the equipment should be easy and quick, as most of the industries do not have specialized staff nor time to spend in preparing a long and complicated test.

There are many patents that propose systems to turn economically feasible, to easy and speed up functional tests in production lines of the electronic industry with low and medium volume of manufactured units. In general, the known solutions apply techniques that require specialists in hardware and software, which make them expensive to be used by the manufacturer of various items with low and medium production volume.

For example, that is the case of the solution proposed in the U.S. Pat. No. 6,311,149 B1 that relates to a reconfigurable test system that includes a master computer coupled to a reconfigurable test instrument and uses FPGA's (Field Programmable Gate Arrays) and FPAA's (Field Programmable Analog Arrays) to be programmed in real time to perform the required functions of each new item to be manufactured. In this solution, the user specifies the functions to be executed by the test instruments using a resident library in the master computer that have the hardware and software configurations, which are transferred to the configurable test instrument, generating a new system architecture with new test functions.

This is an extremely flexible equipment but has a deficiency in requiring that the programmer be a professional specialist, which, besides being an excellent programmer, must know the functioning details of the hardware.

Another disadvantage of this solution is that the operations of synthesis, implementation and programming of the circuits in FPGA are very long, very much increasing the test development time.

U.S. Pat. No. 6,188,288 describes a structure for functional testing of electronic circuit boards UST (Unit Under Test), that includes a controller computer and a test instrument with fixture (bed of nails) with reprogrammable testing pins for each type of the electronic circuit board (UST) to be tested, being the fixture controlled by a program that selects which of the test probes will be activated and command the functions of the testing pins selected to execute the tests. This program is generated in the system control computer, using a proprietary programming language to select and specify the function of each testing pin probe to be used in the functional test of a specific type of electronic PCB (UST). The recurrent problem in this solution is that fixtures with different configurations are needed that can be economically programmed for different families of electronic circuit PCB assembled by the industry, and require a specialist to design the testing programs that will be applied in each case, becoming unaffordable to the common user available in the staff of a small or medium-sized factory.

### DISCLOSURE OF THE INVENTION

The present invention offers an alternative to the state of the art and technique of functional and parametric testing of electronic circuit boards and modules that efficiently covers the existing gaps, incorporates a series of elements and internal structures with advantageous considering performance, programming ease, introduction and operation that are economically justifiable to the manufacturer and assembler of electronic circuit PCB and electronic modules of different types with small and medium variable volume of production, without the disadvantages previously mentioned, such as the personalized and dedicated Test Jigs and the reconfigurable test systems that require specialists for reprogramming. Therefore, the equipment here proposed, “FUNCTIONAL PARAMETRIC TESTER AND EMULATOR OF ELECTRONIC MODULES AND PCBS,” was studied, researched and created.

### BRIEF DESCRIPTION OF THE DRAWINGS

Embodiments of the present invention proposed in this report will be better and fully understood from the accompanying description and following drawings.

FIG. 1 is a block diagram of the Functional Parametric Tester and Emulator of Electronic Modules and PCB's according to the present invention, in one of its embodiment architecture versions.

FIG. 2 is a schematic block diagram of the Functional Parametric Tester and Emulator of Electronic Modules and PCB's, according to the present invention, in another of its embodiment architecture versions.

FIG. 3 is a schematic block diagram of the Programming and Operation Unit (UPO) of the Functional Parametric Tester and Emulator of Electronic Modules and PCB's, according to the present invention.

FIG. 4 presents a schematic block diagram of the programmable test instrument (ITP), of the Functional Parametric Tester and Emulator of Electronic Modules and PCB's, according to the present invention.

### DETAILED DESCRIPTION OF THE INVENTION

The description of a preferred non-restrictive embodiment according to the present invention is presented where the configuration and the application can vary in the appropriate form for each desired model, describing one of the constructive possibilities that makes a reality the described object and the form of functioning in the function of Functional Parametric Tester and Emulator of Electronic Modules and PCB's. With the main objective to simplify and make versatile the functions and applications of this equipment, as well as to reduce costs of manufacture and maintenance, allowing more accessibility to this kind of equipment throughout the industry.

The Functional Parametric Tester and Emulator of Electronic Modules and PCB's, according to the present invention, is an electro-electronic equipment enabling functional and parametric testing of a great variety of circuits, modules or electronic systems 100, that basically includes a programmable test instrument (ITP) 130 coupled to a programming and operation unit (UPO) 110, through a communication interface 120. The UPO has the functions for executing the man machine interface (IHM) of the equipment, besides storing the test program and the test results. The communication interface 120 between the UPO and the ITP can be implemented by any type of electrical or optical communication, such as RS232, RS485, Ethernet, USB, IR, etc. The ITP is the system brain. The ITP interprets the commands generated by the UPO and executes them generating and/or capturing the UST (Unit Under Test) 150 signals 140.

The Programming and Operation Unit is constituted by the following main blocks: a man machine interface (IHM) 200, a microprocessor system (CPU) 210, a non-volatile mass memory (MEM) 220, and a communication interface (ICOM) 230. The UPO can be implemented by small computers available in the market.

The man machine interface (IHM) 200 function is to execute the communication with the operator and can be composed by a keyboard and a display or monitor. It allows the Operator to command the test and visualize the test result and edit the test.

The CPU (microprocessor system) 210 executes a software that allows control of the IHM (man machine interface) 200 and manages the information flow of the UPO (programming and operation unit) 110. The CPU sends to the ITP (programmable test instrument) 130, line by line, the test program stored in the MEM (non volatile mass memory) 220, and at the end of the test, receives the result and displays to operator through the IHM (man machine interface) 200.

The MEM (non volatile mass memory) 220 is a memory non-volatile (HD, Flash, etc.) that stores the program to be executed. Each test is composed by a series of basic operations (commands). Each line of the program represents a command that the ITP (programmable test instrument) 130 can understand and execute through its Library of Electronic Circuits, for example, close relay X, generate sine (amplitude, frequency), set pin X, select Channel X, etc. The MEM is also used to store the test results. The ICOM (communication interface) 230 is a communication interface between the UPO (programming and operation unit) 110 and the ITP (programmable test instrument) 130, which can be any type of electrical or optical communication, such as RS232, RS485, Ethernet, USB, IR, etc.

The Programmable Test Instrument (ITP) 130 is responsible for interpreting the program and the physical execution of the test. The ITP is composed of two modules, the MicroTest (uPT) 300 and the Electronic Circuits Library (BCE).

The Micro Test 300 is a circuit that can interpret and execute the specialized and complex commands in the execution of a test. Actually, it is implemented in a FPGA (Field Programmable Gate Array), but it is possible to implement it in ASIC (Application Specific Integrated Circuit). The MicroTest receives the command from the UPO through the communication interface 120, interprets this command, then generating commands to the BCE 310, through an internal specific bus 320, activating and configuring the circuits that will be used in the test. With the MicroTest, the programmer does not need to understand the hardware details. All the hardware problems are solved by the MicroTest. The programmer must only know the function of each command, making the programming work easy.

The BCE (Electronic Circuits Library) is a set of electronic circuits to be used in the execution of the test.

With the advancement technology of FPGA's, FPAA's, microprocessors, converters, a/d converters, d/a converters, etc., we can now create in a reduced space a great variety of circuits, executing the most diverse functions. It is now possible to create in only one equipment, a circuit library able to do a great variety of tests, such as voltmeter, multimeter, multiplexer, signal generator, audio analyzer, oscilloscope, digital signals input and output, oscillators, pattern generator, communication circuits, etc.

The BCE (Electronic Circuits Library) gives a great flexibility to the equipment, allowing emulation of a large variety of circuits, without the problem of development time and implementation of these circuits, as they will be already present in the hardware, making it necessary to only be configured and activated.

The MicroTest and the BCE structure are feasible, as most tests require only a limited number of commands and circuits to be executed and can be implemented in only one equipment.

One advantage of this architecture is the test speed. As the BCE circuits are independent, we can have real parallel processing. Another factor that contributes to the speed is the command interpretation done by hardware through the MicroTest, significantly reducing the commands execution time, allowing the operator to carry out tests with incredible speed.

The connection between the ITP and the UST is done through a set of connectors. Each connector pin has a special function, depending upon the circuits in the BCE to which is coupled.

Each pin has its function and position mapped inside the MicroTest, which allows the programmer to easily define the pins with which he is working.

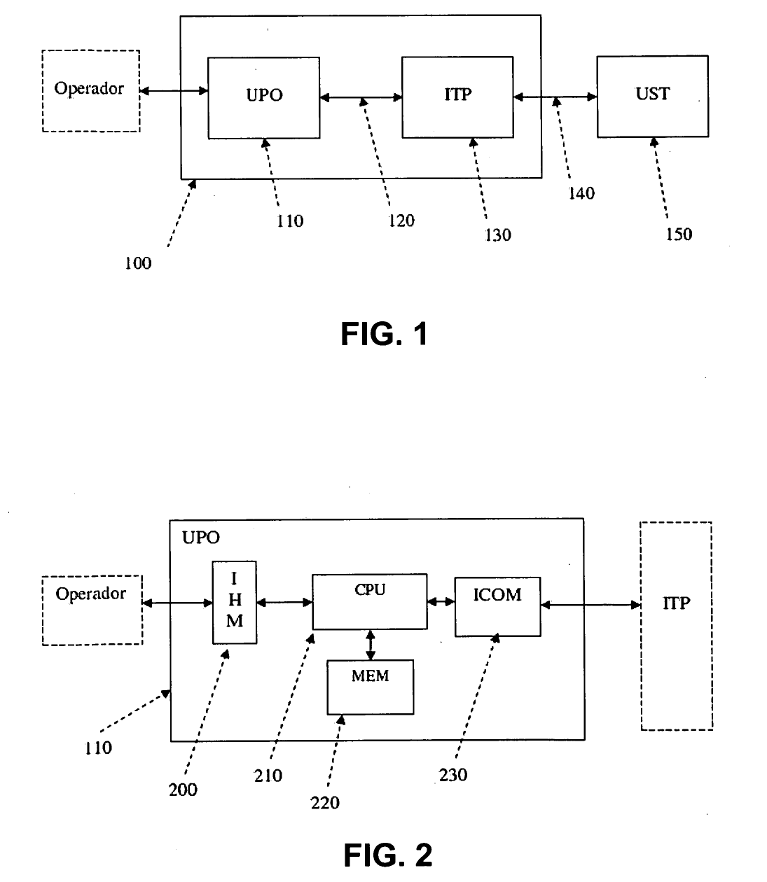

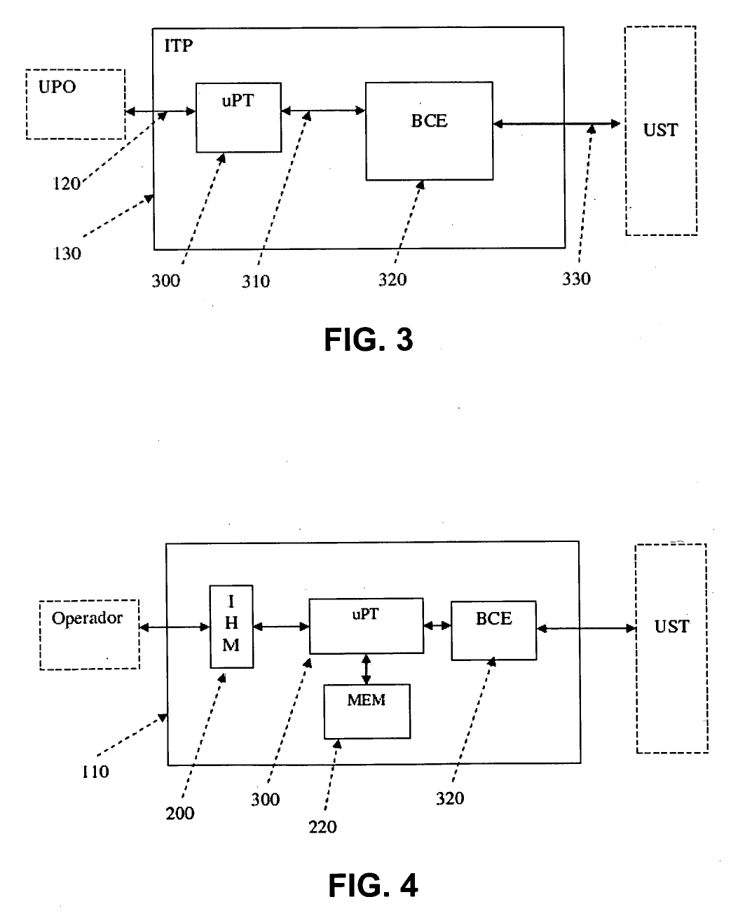

In a new architecture of the Functional Parametric Tester and Emulator equipment of Electronic Modules and electronic PCB's according to this invention, a functional improvement of the system will be the ITP to incorporate the POU functions. With evolution of the FPGA's, it is possible for the development of the MicroTest to have the MMI functions and control a mass memory to store the test program, simplifying the architecture presented in FIG. 1, changing to the architecture presented in FIG. 2. This new architecture allows reducing the physical size of the system and creating smaller equipment.

As one application example, we can quote the introduction of this equipment Functional Parametric Tester and Emulator equipment of Electronic Modules and electronic PCB's for testing terminals boards of telephone switching central offices. These terminal boards operate only when coupled to a telephone central office. To execute the functional test, the terminal board must be connected in the telephone central office, and even so, it is not possible to do the parametric tests (test with parameters variation and storing the test results).

The alternative is to construct a dedicated Test Jig, assembling part of the telephone central office associated to instruments and auxiliary instruments.

This solution presents many disadvantages, such as:
The equipment is extremely complex, requiring a specialized professional to design or to reproduce.
The unitary cost is very high.
Requires a different dedicated equipment for each terminal board model, increasing the cost of each test, as the equipment remains idle if that board is not in production. Other costs is the inventory cost of these Jig's.
As a dedicated system, it does not allow test changes.
Some tests are very slow. Generally, these systems are assembled with circuits and adapted instruments, with some tests becoming very slow.

Installing the Functional Parametric Tester and Emulator equipment of Electronic Modules and electronic PCB's, the object of the present invention, to execute the functional and parametric tests, a Library was developed with basic circuits, such as digital inputs, digital outputs, relay multiplexer, electronic loads, PCM channel 2 Mb/s, modules of relay with dry contacts, voltmeter, signal generator, etc.

With this circuit library (BCE) plus the MicroTest, it is possible to emulate the part that was of our interest in a telephone central office and a regular telephone set. The test program was then developed for each model of board used, with the commands of the MicroTest. When ready, the new system replaced the old one with many advantages as follows:
With only one equipment, it was possible to test all the board models, resulting in space economy and cost.
The test that was being done in 20 minutes, now is being executed in only 3 minutes.
The unitary cost of the equipment was four times lower.
Allowed the test modification in an easy and quick way.
The assembly of new equipment became easy and quick.

Another possible implementation is to test PABX systems using the same equipment Functional Parametric Tester and Emulator of Electronic Modules and PCB's, the object of the present invention, changing only the test software. In this form, it is possible to test a PABX system that demonstrate the equipment flexibility here proposed.

So, for the characteristics of the application, configuration and functioning above described, it can be clearly noted that the Functional Parametric Tester and Emulator of Electronic Modules and PCB's represent an equipment new for the State of the Technique, which assumes unpublished conditions of innovation, inventive activity and industrialization, as well as simplification of manufacturing and utilization, making it deserving of the privilege of a patent of invention.

1. A FUNCTIONAL PARAMETRIC TESTER AND EMULATOR OF ELECTRONIC MODULES AND PCB's, according to the present invention, equipment electro-electronic that allows to do functional and parametric test in a great variety of electronic circuits, modules or systems (100), characterized by a programmable test instrument (ITP) (130), coupled to a programmable and operation unit (UPO) (110), through a communication interface (120); wherein the UPO have functions to execute the man machine interface (IHM) of the equipment besides storing the test program, the test results. The communication interface (120) between the UPO and the ITP may be implemented by any type of electrical or optical interface such as RS232, RS485, Ethernet, USB, IR, and others. The ITP is the brain of the system that interprets the commands generated by the UPO and execute them through generation and/or capturing the UST (150) signals (140), where each test is composed by a series of basic operations (commands) and each program line represent a command that the ITP (programmable test instrument) (130) can understand and execute through its Electronic Circuit Library (BCE).

2. The FUNCTIONAL PARAMETRIC TESTER AND EMULATOR OF ELECTRONIC MODULES AND PCB's of claim 1, wherein the equipment includes a Programming and Operation Unit (UPO) constituted by the following main blocks: a man machine interface (IHM) (200), a local microprocessor system (CPU) (210), a non volatile mass memory (MEM) (220), and a communication interface (ICOM) (230); wherein the CPU (microprocessor system) (210) executes a software that control the IHM (man machine interface) (200), and manages the information flow of the UPO (programmable operation unit) (110), sending to the ITP (programmable tester instrument) (130), line by line of the test program stored in the MEM (non volatile mass memory) (220), that store the program to be executed, and at end of the test receives the results which are displayed to operator through the MMI (man machine interface) (200).

3. The FUNCTIONAL PARAMETRIC TESTER AND EMULATOR OF ELECTRONIC MODULES AND PCB's of claim 1, wherein the equipment includes a man machine interface (IHM) (200) wherein the MMI have the communication function with the operator, wherein the IHM can be constituted by a keyboard and a display or monitor or similar peripheral, wherein the IHM allows an operator to command the test and visualize the test result and also to edit the test.

4. The FUNCTIONAL PARAMETRIC TESTER AND EMULATOR OF ELECTRONIC MODULES AND PCB's of claim 1, wherein the equipment includes a communication interface (ICOM) (230) between the UPO (programmable and operation unit) (110) and the ITP (programmable tester instrument) (130), wherein the interface can be implemented by any type of electrical or optical communication such as RS232, RS485, Ethernet, USB, IR, and others.

5. The FUNCTIONAL PARAMETRIC TESTER AND EMULATOR OF ELECTRONIC MODULES AND PCB's of claim 1, wherein the equipment includes a programmable tester instrument (ITP) (130), wherein the ITP is responsible for the interpretation and physical execution of the test, wherein the PTI is comprised by the hardware module MicroTeste (uPT) (300) and the software Electronic Circuits Library (BCE).

6. The FUNCTIONAL PARAMETRIC TESTER AND EMULATOR OF ELECTRONIC MODULES AND PCB's of claim 1, wherein the equipment includes the circuit MicroTest (300) wherein the MicroTest circuit is able to interpret and process the complex programs specialized in a test execution, wherein the MicroTest is implemented in a device FPGA (Field Programmable Gate Array), in a device ASIC (Application-Specific Integrated Circuit) or any other possible applicable device, wherein the MicroTest receives command from the UPO through the communication interface (ICOM) (120), wherein the MicroTest interprets this command wherein the MicroTest generates commands to the BCE (310) through an internal specific bus (320), wherein such MicroTest commands activate and configure the circuits to be applied in the test.

7. The FUNCTIONAL PARAMETRIC TESTER AND EMULATOR OF ELECTRONIC MODULES AND PCB's of claim 1, wherein the equipment includes an embedded software Electronic Circuits Library (BCE) wherein the BCE comprises a set of electronic circuits oriented to the test execution, wherein the BCE offers a great flexibility to the equipment, wherein the BCE allows to emulate a great variety of circuits that are already in the equipment hardware structure that can be configured and activated.

8. The FUNCTIONAL PARAMETRIC TESTER AND EMULATOR OF ELECTRONIC MODULES AND PCB's of claim 2, wherein the equipment includes a communication interface (ICOM) (230) between the UPO (programmable and operation unit) (110) and the ITP (programmable tester instrument) (130), wherein the interface can be implemented by any type of electrical or optical communication such as RS232, RS485, Ethernet, USB, IR, and others.

9. The FUNCTIONAL PARAMETRIC TESTER AND EMULATOR OF ELECTRONIC MODULES AND PCB's of claim 2, wherein the equipment includes a programmable tester instrument (ITP) (130), wherein the ITP is responsible for the interpretation and physical execution of the test, wherein the PTI is comprised by the hardware module MicroTeste (uPT) (300) and the software Electronic Circuits Library (BCE).

10. The FUNCTIONAL PARAMETRIC TESTER AND EMULATOR OF ELECTRONIC MODULES AND PCB's of claim 2, wherein the equipment includes the circuit MicroTest (300) wherein the MicroTest circuit is able to interpret and process the complex programs specialized in a test execution, wherein the MicroTest is implemented in a device FPGA (Field Programmable Gate Array), in a device ASIC (Application-Specific Integrated Circuit) or any other possible applicable device, wherein the MicroTest receives command from the UPO through the communication interface (ICOM) (120), wherein the MicroTest interprets this command wherein the MicroTest generates commands to the BCE (310) through an internal specific bus (320), wherein such MicroTest commands activate and configure the circuits to be applied in the test.

11. The FUNCTIONAL PARAMETRIC TESTER AND EMULATOR OF ELECTRONIC MODULES AND PCB's of claim 5, wherein the equipment includes the circuit MicroTest (300) wherein the MicroTest circuit is able to interpret and process the complex programs specialized in a test execution, wherein the MicroTest is implemented in a device FPGA (Field Programmable Gate Array), in a device ASIC (Application-Specific Integrated Circuit) or any other possible applicable device, wherein the MicroTest receives command from the UPO through the communication interface (ICOM) (120), wherein the MicroTest interprets this command wherein the MicroTest generates commands to the BCE (310) through an internal specific bus (320), wherein such MicroTest commands activate and configure the circuits to be applied in the test.

12. The FUNCTIONAL PARAMETRIC TESTER AND EMULATOR OF ELECTRONIC MODULES AND PCB's of claim 2, wherein the equipment includes an embedded software Electronic Circuits Library (BCE) wherein the BCE comprises a set of electronic circuits oriented to the test execution, wherein the BCE offers a great flexibility to the equipment, wherein the BCE allows to emulate a great variety of circuits that are already in the equipment hardware structure that can be configured and activated.

13. The FUNCTIONAL PARAMETRIC TESTER AND EMULATOR OF ELECTRONIC MODULES AND PCB's of claim 5, wherein the equipment includes an embedded software Electronic Circuits Library (BCE) wherein the BCE comprises a set of electronic circuits oriented to the test execution, wherein the BCE offers a great flexibility to the equipment, wherein the BCE allows to emulate a great variety of circuits that are already in the equipment hardware structure that can be configured and activated.
